(19) United States
(12) Patent Application Publication
(10) Pub. No.: US 2025/0258017 A1
(43) Pub. Date: Aug. 14, 2025

(54) MAGNETIC DETECTION DEVICE, MAGNETIC DETECTION MODULE, MAGNETIC DETECTION SYSTEM, GEAR DRIVING DETECTION DEVICE, MOTOR DRIVING DETECTION DEVICE, AND ENCODER

(71) Applicant: TDK Corporation, Tokyo (JP)

(72) Inventors: Keiji SUZUKI, Tokyo (JP); Tatsuya KATO, Tokyo (JP)

(73) Assignee: TDK Corporation, Tokyo (JP)

(21) Appl. No.: 19/051,294

(22) Filed: Feb. 12, 2025

(30) Foreign Application Priority Data
Feb. 13, 2024 (JP) 2024-019292

(51) Int. Cl. G01D 5/14; G01R 33/00; G01R 33/07

(52) U.S. Cl. CPC G01D 5/145; G01R 33/0094; G01R 33/072

(57) ABSTRACT

A magnetic detection device includes a first detection unit, a magnet, and a second detection unit, which are arranged in order along one direction. The first detection unit detects a change in magnetism from the magnet occurring when a first projection row, which is constituted by at least one projecting portion provided on a moving body, passes between the first detection unit and the magnet as the moving body moves, and the second detection unit detects a change in the magnetism from the magnet occurring when a second projection row, which is constituted by at least one projecting portion provided on the moving body, passes between the magnet and the second detection unit as the moving body moves.

### CROSS-REFERENCE TO RELATED APPLICATION

The present application is based upon and claims the benefit of priority from Japanese Patent Application No. 2024-019292, filed on Feb. 13, 2024, the entire contents of which are hereby incorporated by reference.

### BACKGROUND

The present disclosure relates to a magnetic detection device, a magnetic detection module, a magnetic detection system, a gear driving detection device, a motor driving detection device, and an encoder.

Various detection devices that detect the rotation angle of a rotating body or detect the displacement position of a linear motion body are available. Among these devices, magnetic detection devices have a characteristic of being able to detect the angle and position of a moving object serving as a detection target without contact, and are therefore widely used even in environments where there are large amounts of disturbance light, dust, and so on that impede sensing. For example, a magnetic detection device is used as a rotation angle detection device for an internal combustion engine (see Patent Publication JP-A-S61-177794, for example).

### SUMMARY

A magnetic detection device according to a first aspect of the disclosure includes a first detection unit, a magnet, and a second detection unit, which are arranged in order along one direction, wherein the first detection unit detects a change in magnetism from the magnet occurring when a first projection row, which is constituted by at least one projecting portion provided on a moving body, passes between the first detection unit and the magnet as the moving body moves, and the second detection unit detects a change in the magnetism from the magnet occurring when a second projection row, which is constituted by at least one projecting portion provided on the moving body, passes between the magnet and the second detection unit as the moving body moves.

Further, a magnetic detection module according to a second aspect of the disclosure includes the magnetic detection device described above, and a base material portion on which the first detection unit, the magnet, and the second detection unit of the magnetic detection device are positioned.

Further, a magnetic detection system according to a third aspect of the disclosure includes both the magnetic detection device described above and the moving body described above.

Further, a gear driving detection device according to a fourth aspect of the disclosure includes the magnetic detection system described above.

Further, a motor driving detection device according to a fifth aspect of the disclosure includes the magnetic detection system described above.

Further, an encoder according to a sixth aspect of the disclosure includes the magnetic detection system described above.

### BRIEF DESCRIPTION OF THE DRAWINGS

The accompanying drawings are included to provide a further understanding of the disclosure and are incorporated in and constitute a part of this specification. The drawings illustrate example embodiments and, together with the specification, serve to explain the principles of the technology.

FIG. 1 is an overall view showing an overall configuration of a magnetic detection system according to a first example;

FIG. 2 is a partial perspective view showing an enlargement of principal parts of the magnetic detection system;

FIG. 3 is an enlarged view of principal parts of a magnetic detection device, illustrating an arrangement and functions thereof;

FIG. 4 is a view showing change in the outputs of respective sensors as a rotating body rotates;

FIG. 5 is a view illustrating a relationship between an interval between adjacent first projecting portions and the width of the first projecting portion;

FIG. 6 is a view showing results of a simulation of a detected magnetic flux distribution relative to a tooth width ratio;

FIG. 7 is a view illustrating a difference in the output of a third sensor depending on the presence or absence of a yoke; and

FIG. 8 is an overall view showing an overall configuration of a magnetic detection system according to a second example.

### DETAILED DESCRIPTION

In the following, some example embodiments and modification examples of the technology are described in detail with reference to the accompanying drawings. Note that the following description is directed to illustrative examples of the disclosure and not to be construed as limiting the technology. Factors including, without limitation, numerical values, shapes, materials, components, positions of the components, and how the components are coupled to each other are illustrative only and not to be construed as limiting the technology. Further, elements in the following example embodiments which are not recited in a most-generic independent claim of the disclosure are optional and may be provided on an as-needed basis. The drawings are schematic and are not intended to be drawn to scale. Like elements are denoted with the same reference numerals to avoid redundant descriptions.

When detecting the rotation angle of a rotating body or detecting the displacement position of a linear motion body, it may be more desirable to detect an absolute rotation angle or displacement position relative to a measurement reference than to detect a relative rotation angle (in other words, a rotation amount) or a relative displacement position (in other words, a displacement amount). In such a case, a detection unit for detecting the measurement reference provided on the moving body is typically provided separately from a detection unit for detecting the relative rotation angle or displacement position. In view of the fact that magnetic detection devices are used in various environments, however, it is desirable to form the device from as few components as possible and as compactly as possible.

The present disclosure has been designed to solve this problem, and provides a magnetic detection device that has a small number of components and can be configured compactly, as well as a magnetic detection module, a magnetic detection system, a gear driving detection device, and a motor driving detection device that include the magnetic detection device.

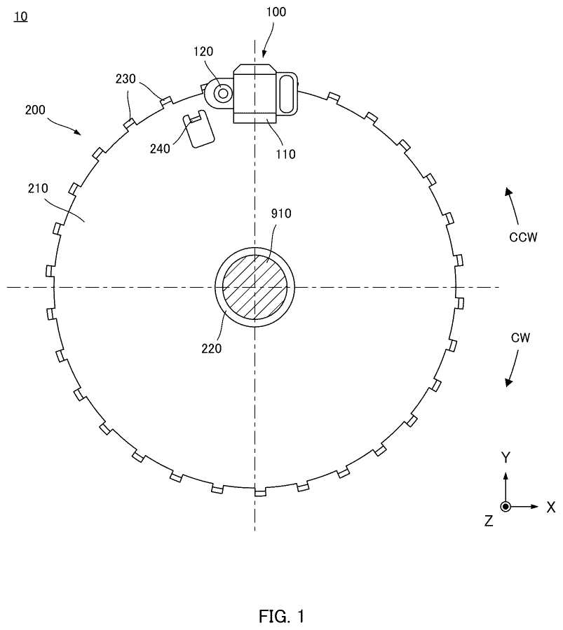

FIG. 1 is an overall view showing an overall configuration of a magnetic detection system 10 according to a first example of this example embodiment. The magnetic detection system 10 is constituted by a rotating body 200 mounted on and fixed to a rotary shaft 910, and a magnetic detection module 100 for detecting the rotation angle of the rotating body 200.

The rotating body 200 is principally constituted by a disc portion 210, a joint portion 220, first projecting portions 230, and a second projecting portion 240. The rotating body 200 is formed as a whole from a plate-like soft magnetic material, and more specifically, the joint portion 220, the first projecting portions 230, and the second projecting portion 240 are created by punching and bending.

The disc portion 210 functions as a base material of the rotating body 200. Thinning processing may be implemented on the disc portion 210 in a radial direction, for example. The joint portion 220 functions as a mounting portion for mounting the rotating body 200 on the rotary shaft 910. The joint portion 220 may be caulked to the rotary shaft 910 or mounted via an attachment/detachment mechanism. By mounting the rotating body 200 on the rotary shaft 910 via the joint portion 220, the rotating body 200 rotates integrally with the rotary shaft 910. Note that in this example, the rotary shaft 910 is described as being capable of rotating both clockwise (CW) and counterclockwise (CCW), as shown in the figure.

The first projecting portions 230 are provided in a plurality in a circumferential direction around the peripheral edge of the disc portion 210. More specifically, the first projecting portions 230 are respectively formed by bending tongue pieces provided radially on a peripheral edge part of the disc portion 210 so as to stand upright relative to the plane of the disc portion 210. The width direction of the first projecting portions 230 formed in this manner is a direction extending along the circumferential direction of the disc portion 210. In this example, a case in which 30 first projecting portions 230 are formed at equal intervals around the peripheral edge of the disc portion 210 will be described as an example. The first projecting portions 230 erected along the circumferential direction collectively constitute a first projection row.

The second projecting portion 240 is formed on the inner peripheral side of the peripheral edge of the disc portion 210, on which the first projecting portions 230 are provided, by bending a tongue piece formed by punching so as to stand upright relative to the plane of the disc portion 210, similarly to the first projecting portions 230. The width direction of the second projecting portion 240, similarly to the width direction of the first projecting portions 230, is a direction extending along the circumferential direction of the disc portion 210. As will be described below, the second projecting portion 240 may be provided in a plurality on concentric circles, but in this example, a case in which the second projecting portion 240 is formed singly on the inner peripheral side of the peripheral edge of the disc portion 210 will be described as an example. The one or more second projecting portions 240 formed in this manner are assumed to collectively constitute a second projection row.

The magnetic detection module 100 is attached and fixed to a support, not shown in the figures, via an attachment portion 120. A housing 110 of the magnetic detection module 100 functions as a base material portion for positioning respective elements of a magnetic detection device, to be described below. The magnetic detection device provided in the housing 110 detects the first projecting portions 230 of the first projection row and the second projecting portion 240 of the second projecting row, which move relative to the magnetic detection module 100, by changes in magnetism.

Note that in this example, as indicated by coordinate axes in the figure, a rotary axis direction of the rotary shaft 910 is defined as a Z-axis direction, and the two axes that are orthogonal to the Z-axis direction are defined as an X-axis direction and a Y-axis direction. Similar coordinate axes, based on a state in which the magnetic detection system 10 is arranged as shown in FIG. 1, have also been added to subsequent figures to indicate the orientations of structures depicted in the figures.

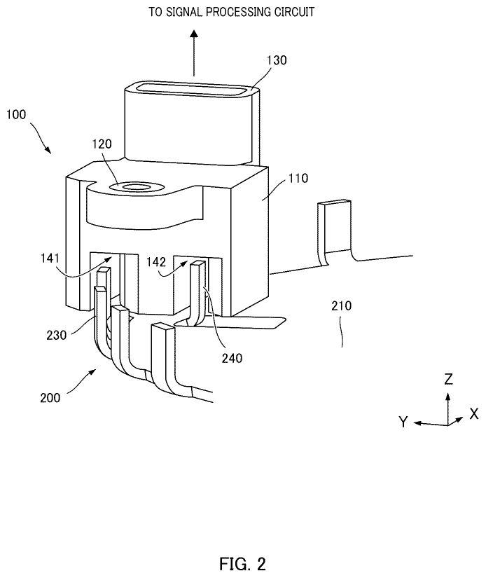

FIG. 2 is a partial perspective view showing an enlargement of principal parts of the magnetic detection system 10. The housing 110 of the magnetic detection module 100 supports the respective elements of the magnetic detection device, and output signals from magnetic sensors, to be described below, are output to a signal processing unit through a connector, not shown in the figures, inserted into a connector insertion port 130.

The housing 110 includes a first slit 141 and a second slit 142. The first slit 141 is a space through which the rotating first projecting portions 230 pass. The second slit 142 is similarly a space through which the rotating second projecting portion 240 passes. Although described more specifically below, magnetic sensors detect magnetism that changes as the first projecting portions 230 pass through the first slit 141 and magnetism that changes as the second projecting portion 240 passes through the second slit 142.

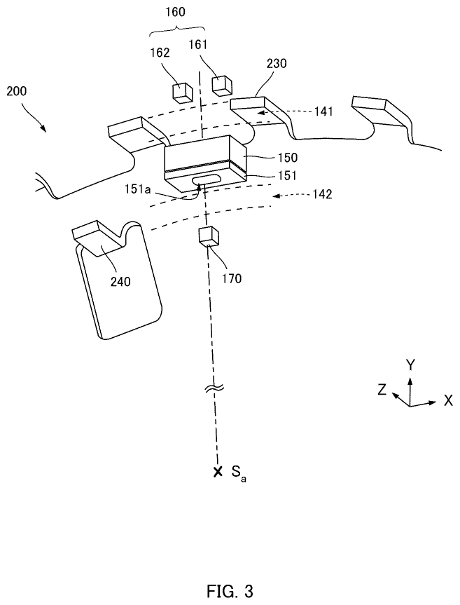

FIG. 3 is an enlarged view of principal parts of a magnetic detection device, illustrating an arrangement and functions thereof. The magnetic detection device includes a first detection unit 160, a magnet 150, a yoke 151, and a second detection unit 170, which are arranged along a straight line (indicated in the figure by a dot-dash line) parallel to a Y-axis that passes through a center of rotation Sₐ of the rotating body 200. In this example, the first detection unit 160 is constituted by a first sensor 161 and a second sensor 162, and these sensors are arranged along the movement direction of the first projecting portions 230 so as to sandwich the aforementioned straight line. The respective elements of the first detection unit 160, the magnet 150, the yoke 151, and the second detection unit 170 are supported and fixed in set positions of the housing 110 shown in FIGS. 1 and 2. Note, however, that in FIG. 3, apart from dotted lines indicating the space of the first slit 141 and the space of the second slit 142, depiction of the housing 110 has been omitted.

The first sensor 161 and second sensor 162 forming the first detection unit 160 are both magnetic sensors, for example linear-type Hall ICs. As the rotating body 200 rotates, the first projecting portions 230 pass through the first slit 141, which is set between the magnet 150 and the first and second sensors 161 and 162. Although described more specifically below, when the first projecting portion 230 passes through the first slit 141, magnetism from the magnet 150 is temporarily blocked, and accordingly, the first sensor 161 and the second sensor 162 each output an analog signal corresponding to the passage of the first projecting portion 230.

In this example, the second detection unit 170 is constituted by a single magnetic sensor, and is referred to here as a third sensor 170. The third sensor 170 is a switch-type Hall IC, for example. As the rotating body 200 rotates, the second projecting portion 240 passes through the second slit 142, which is set between the magnet 150 and the third sensor 170. Although described more specifically below, when the second projecting portion 240 passes through the second slit 142, magnetism from the magnet 150 is temporarily blocked, and accordingly, the third sensor 170 outputs a binary signal (a digital signal) corresponding to the passage of the second projecting portion 240.

The magnet 150 is a permanent magnet, and in this example, since Hall ICs are employed as the magnetic sensors, the magnetization direction thereof is a direction parallel to the direction indicated by the dot-dash line. The yoke 151 is disposed adjacent to a surface of the magnet 150 on the third sensor 170 side in order to limit magnetism traveling from the magnet 150 to the third sensor 170. The yoke 151 has an opening portion 151a near the center, and the opening portion 151a contributes to limitation of the magnetism traveling from the magnet 150 to the third sensor 170. Specific functions of the yoke 151 and the opening portion 151a will be described below.

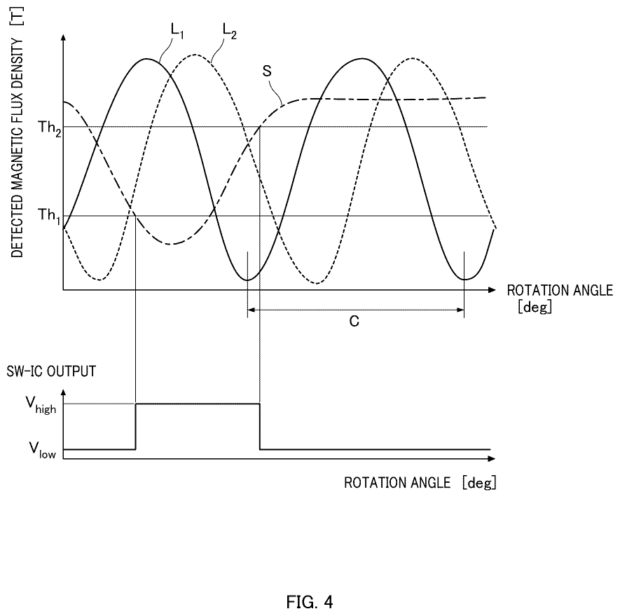

FIG. 4 is a view showing change in the outputs of the respective sensors as the rotating body 200 rotates. The upper diagram of FIG. 4 shows the analog signal outputs of the respective sensors when the rotating body 200 rotates counterclockwise (CCW), and more specifically shows states before and after the second projecting portion 240 passes through the second slit 142. The horizontal axis shows the rotation angle (deg), and the vertical axis shows detected magnetic flux density (T). A solid line L₁ represents the output of the first sensor 161, a solid line L₂ represents the output of the second sensor 162, and a dot-dash line S represents the output of the third sensor 170 at the analog stage.

The output of the first sensor 161 decreases as the first projecting portion 230 nears the space between the first sensor 161 and the magnet 150, and increases as the first projecting portion 230 moves away. When one projecting portion 230 passes through, the output signal thereof forms a substantially sinusoidal curve corresponding to one wavelength, and the sinusoidal curve increases and decreases repeatedly as the respective first projecting portions 230 pass through. In other words, when the rotation speed of the rotating body 200 is constant, the output of the first sensor 161 is a substantially sinusoidal signal of a fixed period. Further, an interval C in the figure, which serves as a bottom-to-bottom interval of the output, represents a rotation angle corresponding to adjacent first projecting portions 230, and since in this example, as described above, 30 first projecting portions 230 are provided around the peripheral edge of the disc portion 210, the interval C corresponds to 12°.

The output of the second sensor 162 is similar to the output of the first sensor 161. More specifically, the output of the second sensor 162 decreases as the first projecting portion 230 nears the space between the second sensor 162 and the magnet 150, and increases as the first projecting portion 230 moves away. The second sensor 162 is disposed at a distance from the first sensor 161 in the movement direction of the first projecting portions 230. Therefore, when the rotation direction of the rotating body 200 is counterclockwise, the output of the second sensor 162 exhibits changes that follow the output of the first sensor 161 at a delay, as shown in the figure. Furthermore, when the rotation direction of the rotating body 200 is clockwise, conversely, the output of the first sensor 161 exhibits changes that follow the output of the second sensor 162 at a delay. Thus, by forming the first detection unit 160 from two sensors (the first sensor 161 and the second sensor 162) arranged in the movement direction of the first projecting portions 230, as in this example, and observing changes in the respective outputs thereof, the rotation direction of the rotating body 200 can also be detected.

In this example, the first projecting portions 230 are provided in a plurality at fixed intervals around the peripheral edge of the disc portion 210, and therefore the respective outputs of the first sensor 161 and the second sensor 162 exhibit periodic changes, as described above. Meanwhile, the second projecting portion 240, as described above, is provided singly slightly inside of the peripheral edge of the disc portion 210. Accordingly, the internal analog signal of the third sensor 170 is fixed when the second projecting portion 240 is sufficiently distanced therefrom, decreases as the second projecting portion 240 nears the space between the magnet 150 and the third sensor 170, and increases as the second projecting portion 240 moves away, thereby exhibiting change for returning to a fixed output.

As noted above, the third sensor 170 is a switch-type Hall IC. Accordingly, when the value of the internal analog signal decreases below a threshold Th₁, as shown by the lower diagram in FIG. 4, the binary output of the IC switches from V_{low} to V_{high}, and when the value of the internal analog signal returns to a threshold Th₂, the binary output of the IC switches from V_{high} to V_{low}. The signal processing circuit can determine the attitude of the rotating body 200 at the point where the binary output of the IC switches from V_{low} to V_{high}, for example, as a measurement reference (for example, rotation angle=0°). By observing the changes in the outputs of the first sensor 161 and the second sensor 162 from this reference point, the rotation angle of the rotating body 200 from the measurement reference can be calculated. In other words, the attitude of the rotating body 200 at the measurement point can be specified.

The outputs of the first sensor 161 and the second sensor 162 were described above as depicting substantially sinusoidal curves. When the outputs depict sinusoidal curves, the rotation angle at a point between two adjacent first projecting portions 230 can also be calculated using an inverse trigonometric function. Hence, when the rotation angle of the rotating body 200 is to be measured as a continuous value, it is necessary for the output of at least one of the first sensor 161 and the second sensor 162 to be a sinusoidal curve. However, in order for the output to depict a sinusoidal curve, the arrangement positions and so on of the magnet 150, the first sensor 161, and the second sensor 162 must be adjusted, and the shape of the first projecting portions 230 must also be considered.

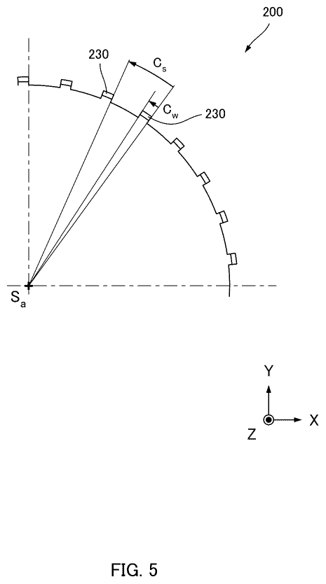

FIG. 5 is a view illustrating a relationship between the interval between adjacent first projecting portions 230 and the width of the first projecting portion 230. As shown in the figure, as the interval between adjacent first projecting portions 230, an angle formed by diameters connected to the center of rotation Sₐ of the rotating body 200 is set as C_{S}. In this example, 30 first projecting portions 230 are provided around the peripheral edge of the disc portion 210, and therefore C_{S}=12°. Further, an angle formed by diameters respectively connecting the two ends of the width of the first projecting portion 230 to the center of rotation Sₐ is set as C_{W}. Accordingly, a ratio R_{c} of the width of the first projecting portion 230 to the interval between two adjacent first projecting portions 230 can be defined as R_{c}=C_{W}/C_{S}.

When R_{c} is small, the first sensor 161 is blocked by the first projecting portion 230 by only a small amount, and therefore the period in which the first sensor 161 directly receives the magnetism of the magnet 150 becomes longer. As a result, a flat part occurs at the maximum value of the solid line L₁ shown in FIG. 4, which is the output curve of the first sensor 161. Conversely, when R_{c} is large, the period in which the first sensor 161 is blocked by the first projecting portion 230 lengthens such that the period in which the first sensor 161 directly receives the magnetism of the magnet 150 becomes shorter. As a result, a valley shape including the minimum value of the solid line L₁ shown in FIG. 4, which is the output curve of the first sensor 161, becomes shallower and smaller. This applies likewise to the output of the second sensor 162. In other words, if R_{c} is not within an appropriate range, the sensor output does not depict a sinusoidal curve.

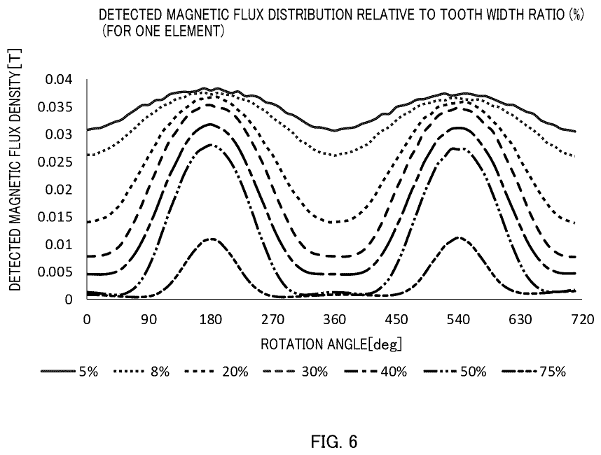

As a result of a process of trial and error conducted by the inventor, it was found that when R_{c} is no less than 8% and no more than 40%, the sensor output can easily be adjusted to a sinusoidal curve. FIG. 6 is a view showing results of a simulation of a detected magnetic flux distribution relative to a tooth width ratio (R_{c}), carried out by the inventor. The horizontal axis shows the rotation angle (deg), and the vertical axis shows the detected magnetic flux density (T). As indicated in the legend, the curves represent change when R_{c} is 5%, 8%, 20%, 30%, 40%, 50%, and 75%, respectively. It can be seen from this diagram that R_{c} can be handled substantially as a sine wave when no less than 8% and no more than 40%. The waveform at 20% particularly closely resembles a sine wave, and it can therefore be said that R_{c} is preferably within a range of no less than 10% and no more than 30%, for example. Hence, by employing in the rotating body 200 a first projection row constituted by a group of first projecting portions 230 adjusted so that R_{c} is within this range, the arrangement of the magnet 150 and the respective sensors can be adjusted comparatively easily, and as a result, the sensors can be caused to output curves that at least resemble sinusoidal curves.

The second slit 142 is provided further toward the side of the center of rotation Sₐ than the position in which the magnet 150 is disposed. The third sensor 170 is provided even further toward the side of the center of rotation Sₐ. Due to this, the area in which the third sensor 170 can be disposed is often limited. Generally, it is desirable to dispose the third sensor 170 in an optimal arrangement with respect to the magnet 150 in order to obtain an appropriate output, similarly to the first sensor 161 and the second sensor 162, but in the case of the third sensor 170, such an optimal arrangement is difficult. Hence, in this example, in order to obtain an appropriate output even when the third sensor 170 is disposed within a limited area, the yoke 151 is disposed adjacent to the surface of the magnet 150 on the third sensor 170 side. The yoke 151 functions to adjust the magnetism that reaches the third sensor 170 from the magnet 150.

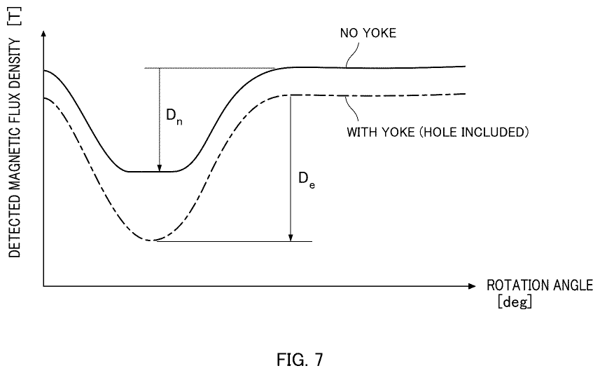

FIG. 7 is a view illustrating a difference in the output of the third sensor 170 depending on the presence or absence of the yoke 151. The horizontal axis shows the rotation angle (deg), and the vertical axis shows the detected magnetic flux density (T). A solid line represents the output of the third sensor 170 at the analog stage when the yoke 151 is not disposed, and a dot-dash line represents the output of the third sensor 170 at the analog stage when the yoke 151 is disposed.

In many cases, the position in which the third sensor 170 is disposed is limited to an area near the magnet 150. By disposing the third sensor 170 in an area near the magnet 150, the overall size of the magnetic detection module 100 can be reduced. With this arrangement, however, as indicated by the solid line, the magnetic flux density detected by the third sensor 170 becomes larger overall, and the amount by which the magnetic flux density decreases (Dₙ in the figure) when the second convex portion 240 passes by is insufficient, resulting in a flat part near the valley bottom.

However, when the yoke 151 is provided, as shown by the dot-dash line, even if the third sensor 170 is disposed in the same position, the magnetic flux density detected by the third sensor 170 becomes slightly smaller overall so that when the second convex portion 240 passes by, a V-shaped valley indicating a large decrease amount (Dₑ in the figure) is formed. In this example in particular, the opening portion 151a is provided in the yoke 151, and therefore the decrease amount Dₑ becomes even larger. In other words, the magnetic flux density detected when the second projecting portion 240 passes by changes by a larger amount. When the detected magnetic flux density changes by a large amount in this manner, the timing at which V_{low} switches to V_{high} becomes more stable, and as a result, the measurement reference can be detected with greater accuracy.

Note that the size of the opening portion 151a provided in the yoke 151 is determined as appropriate in accordance with the magnetic force of the magnet 150 and the position in which the third sensor 170 is disposed, and depending on these conditions, there may be cases where the opening portion 151a is not provided. The opening portion 151a may be formed in the shape of a slit in the yoke 151 (for example, an aspect in which the yoke 151 is constituted by two independent pieces with a gap therebetween). Further, the yoke 151 may be formed in a C shape. In other words, the yoke 151 may be formed so as not to cover a part of the magnet 150. Furthermore, in this example, the yoke 151 is disposed adjacent to the surface of the magnet 150 on the third sensor 170 side, but depending on the relationship between the magnet 150 and the first and second sensors 161 and 162, the yoke 151 may be disposed adjacent to the surface on the side of these sensors. In this case, two opening portions 151a may be provided so as to correspond respectively to the first sensor 161 and the second sensor 162.

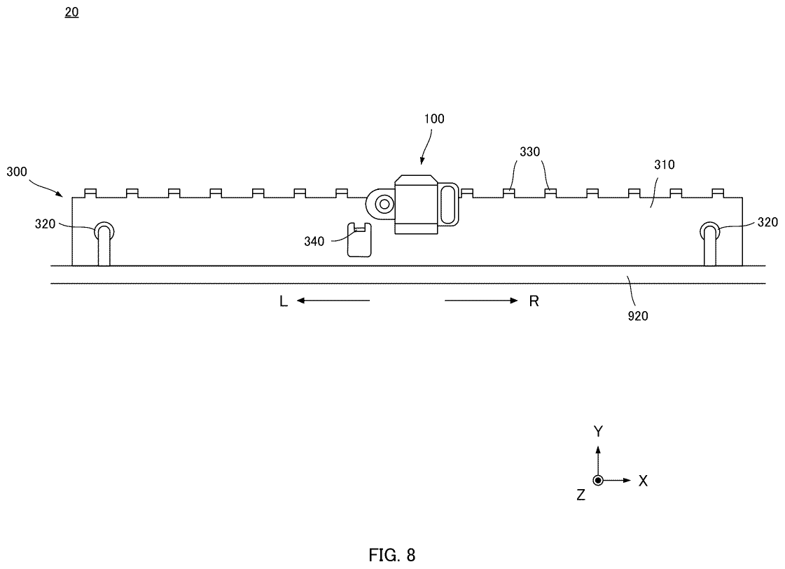

Next, a second example relating to this example embodiment will be described. FIG. 8 is an overall view showing an overall configuration of a magnetic detection system 20 according to the second example. In the magnetic detection system 10 according to the first example, the moving body serving as the detection target of the magnetic detection module 100 was the rotating body 200. In other words, the magnetic detection system 10 was a system for detecting the rotation angle of the rotating body 200, and accordingly the rotary shaft 910. In the magnetic detection system 20 according to the second example, the moving body serving as the detection target of the magnetic detection module 100 is a linear motion body 300 that reciprocates in a horizontal direction (the X-axis direction in FIG. 8), for example.

The magnetic detection system 20 is constituted by the linear motion body 300, which is mounted on and fixed to a reciprocating slider 920, and the magnetic detection module 100. In this example, the magnetic detection module 100 detects a displacement position of the linear motion body 300, and accordingly the reciprocating slider 920.

The linear motion body 300 is principally constituted by a flat plate portion 310, a joint portion 320, first projecting portions 330, and a second projecting portion 340. The linear motion body 300 is formed as a whole from a plate-like soft magnetic material, and more specifically, the joint portion 320, the first projecting portions 330, and the second projecting portion 340 are created by punching and bending.

The flat plate portion 310 functions as a base material of the linear motion body 300. The joint portion 320 functions as a mounting portion for mounting the linear motion body 300 on the reciprocating slider 920. By mounting the linear motion body 300 on the reciprocating slider 920 via the joint portion 320, the linear motion body 300 performs a linear motion integrally with the reciprocating slider 920. Note that in this example, the reciprocating slider 920 is described as performing a reciprocating motion in a rightward direction (R) and a leftward direction (L), as shown in the figure.

The first projecting portions 330 are provided in a plurality along the linear motion direction on one side edge of the flat plate portion 310. More specifically, the first projecting portions 330 are respectively formed by bending tongue pieces provided in comb tooth form on a side edge part of the flat plate portion 310 so as to stand upright relative to the plane of the flat plate portion 310. The width direction of the first projecting portions 330 formed in this manner is a direction extending along a lengthwise direction (the linear motion direction) of the flat plate portion 310. The first projecting portions 330 erected along the lengthwise direction collectively constitute the first projection row.

The second projecting portion 340 is formed on the inside of the side edge of the flat plate portion 310 on which the first projecting portions 330 are provided by bending a tongue piece formed by punching so as to stand upright relative to the plane of the flat plate portion 310, similarly to the first projecting portions 330. The width direction of the second projecting portion 340, similarly to the width direction of the first projecting portions 330, is a direction extending along the lengthwise direction of the flat plate portion 310. The second projecting portion 340 may be provided in a plurality along the lengthwise direction, but in this example, one second projecting portion 340 is formed on the inside of the side edge of the flat plate portion 310. The one or more second projecting portions 340 formed in this manner are assumed to collectively constitute the second projection row.

The configuration of the magnetic detection module 100 is similar to that of the magnetic detection module 100 of the first example. In the magnetic detection system 20 having this configuration, the first sensor 161 and the second sensor 162 detect the first projecting portions 330 passing through the first slit 141, and the third sensor 170 detects the second projecting portion 340 passing through the second slit 142. More specifically, the first sensor 161 and the second sensor 162 detect a displacement amount of the linear motion body 300 by detecting the first projecting portions 330 arranged at fixed intervals, while the third sensor 170 detects a reference position of the linear motion body 300 by detecting the second projecting portion 340. The signal processing circuit can calculate the absolute position of the linear motion body 300 from these detection results.

The first and second examples described above may be subjected to various modifications. For example, the respective projecting portions are not limited to a case in which plate-shaped members are bent, and instead, the projecting portions may be manufactured separately from the base material portion, i.e., the disc portion or the flat plate portion, and attached to the base material portion. Moreover, the base material portion may be divided into a first base material portion including the first projection row and a second base material portion including the second projection row, and after adjusting the respective positions thereof, the base material portion may be mounted on the drive subject, i.e., the rotary shaft 910 or the reciprocating slider 920. In this case, the base material portion does not have to be a soft magnetic material. Furthermore, the magnetic sensors do not have to be Hall ICs, and MR elements, for example, may be used instead. In this case, the magnetization direction of the magnet may be changed in accordance with the used magnetic sensors.

Moreover, in the first and second examples described above, the second projecting portion forming the second projection row is provided singly, but when a plurality of reference positions to be detected are set, the number of second projecting portions may be increased in accordance therewith. Furthermore, the first projection row is arranged on an edge portion of the base material portion of the moving body, and the second projection row is arranged on the inside thereof, but the arrangement of the projection rows may be reversed.

Moreover, in the first and second examples described above, examples in which the first detection unit 160 is constituted by two sensors (the first sensor 161 and the second sensor 162) were described, but in a case where there is no need to detect the movement direction of the moving body or the like, the first detection unit 160 may be formed from a single sensor. In this case, similarly to the first and second examples, the first detection unit, the magnet, and the second detection unit may be arranged along one direction that is orthogonal to the movement direction of the moving body. Note that here, “orthogonal” is not strictly limited to 90°, and may refer to any range in which the first detection unit and the second detection unit can detect the magnetism of the magnet, as described above. With this arrangement, the magnetic detection device and the magnetic detection module including the magnetic detection device can be formed compactly. Here, “arranged along one direction” is not limited to a case in which the components are aligned on one straight line, and as long as the magnetic detection device and the magnetic detection module including the magnetic detection device can be formed compactly, it is sufficient for the components to be aligned along one virtual line when seen as a whole.

Furthermore, the magnetic detection systems 10 and 20 of the first and second examples described above are particularly effective when incorporated into a gear driving detection device or a motor driving detection device. Devices driven by a gear or a motor are often used in dusty or oily environments, but even in such environments, measurement results are less likely to be affected than with a contact-type or optical detection device. The magnetic detection systems 10 and 20 of the first and second examples may also be used favorably when incorporated into an encoder that is also often used in such environments.

According to the above example embodiment, it is possible to provide a magnetic detection device that has a small number of components and can be configured compactly, as well as a magnetic detection module, a magnetic detection system, a gear driving detection device, and a motor driving detection device that include the magnetic detection device.

1. A magnetic detection device comprising a first detection unit, a magnet, and a second detection unit, which are arranged in order along one direction,
wherein the first detection unit detects a change in magnetism from the magnet occurring when a first projection row, which is constituted by at least one projecting portion provided on a moving body, passes between the first detection unit and the magnet as the moving body moves, and
the second detection unit detects a change in the magnetism from the magnet occurring when a second projection row, which is constituted by at least one projecting portion provided on the moving body, passes between the magnet and the second detection unit as the moving body moves.

2. The magnetic detection device according to claim 1, wherein the first detection unit includes at least two magnetic sensors arranged along a movement direction of the moving body.

3. The magnetic detection device according to claim 1, wherein the magnet includes a yoke on either a first surface side opposing the first detection unit or a second surface side opposing the second detection unit.

4. The magnetic detection device according to claim 3, wherein the yoke includes an opening portion through which the magnetism of the magnet passes.

5. The magnetic detection device according to claim 1, wherein a magnetization direction of the magnet is a direction parallel to the one direction.

6. The magnetic detection device according to claim 1, wherein the number of projecting portions constituting the second projection row is smaller than the number of projecting portions constituting the first projection row,
the first detection unit outputs change in the magnetism from the magnet as an analog signal, and
the second detection unit outputs change in the magnetism from the magnet as a digital signal.

7. A magnetic detection module comprising:
the magnetic detection device according to claim 1; and
a base material portion on which the first detection unit, the magnet, and the second detection unit are positioned.

8. A magnetic detection system comprising:
the magnetic detection device according to claim 1; and
the moving body.

9. The magnetic detection system according to claim 8, wherein a ratio of the width of the projecting portion constituting the first projection row to an interval between two adjacent projecting portions constituting the first projection row in the movement direction of the moving body is no less than 8% and no more than 40%.

10. The magnetic detection system according to claim 8, wherein the moving body is a rotating body having a center of rotation on a straight line extending in the one direction, and
the magnetic detection device detects the rotation angle of the rotating body.

11. The magnetic detection system according to claim 8, wherein the moving body is a linear motion body that moves along a straight line orthogonal to the one direction, and
the magnetic detection device detects the position of the linear motion body.

12. A gear driving detection device comprising the magnetic detection system according to claim 8.

13. A motor driving detection device comprising the magnetic detection system according to claim 8.

14. An encoder comprising the magnetic detection system according to claim 8.
